(19) United States
(12) Patent Application Publication
(10) Pub. No.: US 2007/0181996 A1
(43) Pub. Date: Aug. 9, 2007

(54) CIRCUIT BOARD

(75) Inventors: Arthur Chang, Taipei (TW); Fu-Ming Chen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ASUSTEK COMPUTER INC., Taipei (TW)

(21) Appl. No.: 11/616,902

(22) Filed: Dec. 28, 2006

(30) Foreign Application Priority Data
Feb. 7, 2006 (TW) 95104014

(51) Int. Cl. H01L 23/053

(52) U.S. Cl. 257/701

(57) ABSTRACT

A circuit board including a first surface, a second surface, and a third surface is provided. The first surface has a first conductive region, and the second surface is opposite to the first surface. The third surface located between the first surface and the second surface and is connected with the first surface and the second surface. The third surface has a second conductive region, and the first conductive region is electrically connected to at least a part of the second conductive region. The circuit board has good electromagnetic compatibility.

### CROSS-REFERENCE TO RELATED APPLICATION

This application claims the priority benefit of Taiwan application serial no. 95104014, filed Feb. 7, 2006. All disclosure of the Taiwan application is incorporated herein by reference.

### BACKGROUND OF THE INVENTION

1. Field of the Invention

The present invention relates to a circuit board. More particularly, the present invention relates to a circuit board being capable of good electromagnetic compatibility (EMC).

2. Description of Related Art

Electromagnetic compatibility (EMC) is a key quality indicator in the evaluation standards of various electronic devices. The evaluation of EMC includes electromagnetic interference (EMI) and electromagnetic susceptibility (EMS). EMI refers to whether an electronic device itself will affect other electronic devices electromagnetically, and EMS refers to whether an electronic device itself will not be able to work properly due to the electromagnetic interference by other electronic devices.

Generally, the density of the electronic components installed in a circuit board of an electronic device is very high. In such condition, the signal transmits among the electronic components within the circuit board will being affected by each other and a phenomenon of cross talk will be produced. In addition, presently most electronic components transmits signals with high frequency, thus, EMI can be induced easily between the electronic components disposed within an electronic device, and further the operation of the electronic device will be affected.

To prevent electromagnetic waves from the external of the electronic device from interfering signal transmitting within the electronic device, or to prevent electromagnetic waves produced by the signal transmitting within the electronic device from being radiated to the external of the electronic device, the casing of the electronic device used for containing and protecting the electronic components usually uses conductive material (for example, metal), or a conductive layer formed on the surface of the casing so as to provide electromagnetic shielding effect, or a metal cover is constructed at the external of a particular electronic component on the circuit board for providing electromagnetic shielding.

### SUMMARY OF THE INVENTION

Accordingly, the present invention is directed to provide a circuit board having good electromagnetic compatibility (EMC).

To achieve the aforementioned and other objectives, a circuit board including a first surface, a second surface, and a third surface is provided. The first surface has a first conductive region, and the second surface is opposite to the first surface. The third surface disposed between the first surface and the second surface is connected to the first surface and the second surface. The third surface has a second conductive region, and the first conductive region is electrically connected to at least a part of the second conductive region.

In an embodiment of the present invention, the first conductive region is a ground region.

In an embodiment of the present invention, the first surface has a trace, the first conductive region is a bare copper, and the trace connects the first conductive region and the second conductive region.

In an embodiment of the present invention, the second conductive region is a printed conductive layer, an electroplated conductive layer, a sputtered conductive layer, or a dipped conductive layer.

A circuit board including a first conductive region, a first surface, a second surface, and a third surface is further provided. The first conductive region is disposed inside the circuit board and the second surface is opposite to the first surface. The third surface disposed between the first surface and the second surface is connected to the first surface and the second surface. The third surface has at least one second conductive region, and the first conductive region is electrically connected to at least a part of the second conductive region.

In an embodiment of the present invention, the first conductive region is a ground region.

In an embodiment of the present invention, the second conductive region is a printed conductive layer, an electroplated conductive layer, a sputtered conductive layer, or a dipped conductive layer.

According to the present invention, the second conductive region is formed on the third surface of the circuit board to serve as a metal shield of the circuit board, thus, the circuit board has good EMC.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a diagram of a circuit board according to the first embodiment of the present invention.

FIG. 1B is a cross-sectional view of FIG. 1A along line A-A.

FIG. 2 is a cross-sectional view of a circuit board according to the second embodiment of the present invention.

FIG. 3A is a diagram of a circuit board according to the third embodiment of the present invention.

FIG. 3B is a cross-sectional view of FIG. 3A along line B-B.

FIG. 4 is a cross-sectional view of a circuit board according to the fourth embodiment of the present invention.

FIG. 5A is a diagram of a circuit board according to the fifth embodiment of the present invention.

FIG. 5B is a cross-sectional view of FIG. 5A along line C-C.

### DESCRIPTION OF EMBODIMENTS

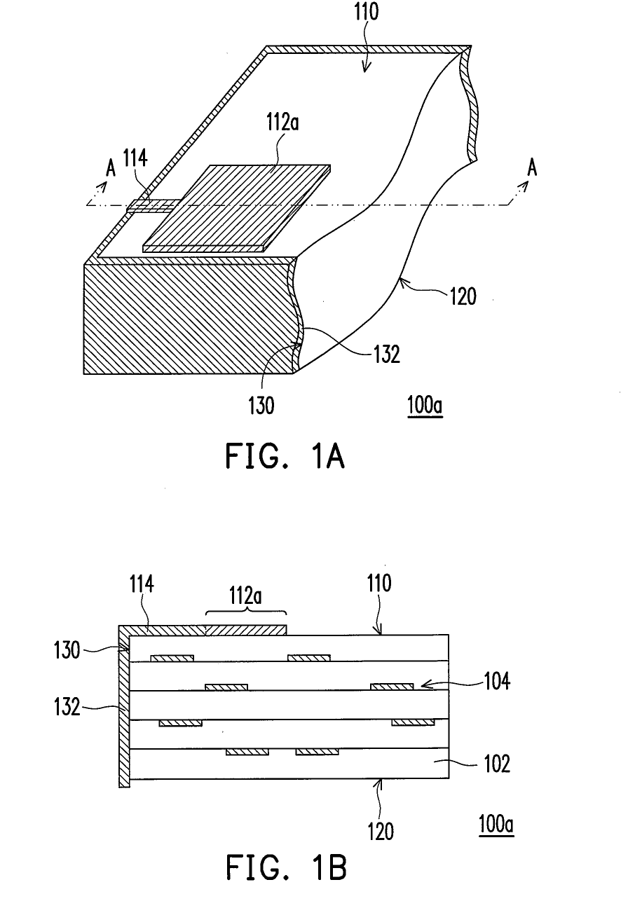

FIG. 1A is a diagram of a circuit board according to the first embodiment of the present invention. Referring to FIG. 1A, the circuit board 100a includes a first surface 110, a second surface 120, and a third surface 130. The first surface 110 has a first conductive region 112a, and the first conductive region 112a is a bare copper. The second surface 120 is opposite to the first surface 110, and the third surface 130 is connected with the first surface 110 and the second surface 120, wherein the third surface 130 has at least one second conductive region 132, and the first conductive region 112a is electrically connected to at least a part of the second conductive region 132.

FIG. 1B is a cross-sectional view of FIG. 1A cut along line A-A. Referring to both FIG. 1A and FIG. 1B, the circuit board 100a in the present embodiment is formed by a plurality of circuit layers 104 and a plurality of insulating layers 102, wherein the circuit layers 104 include a trace 114, and the first conductive region 112a is electrically connected to the second conductive region 132 through the trace 114. In addition, an insulating layer 102 is disposed between two adjacent circuit layers 104. The electronic components (not shown) on the circuit board 100a transmit signals through the circuit layers 104, wherein the circuit layers 104 can be electrically connected with each other through the buried vias (not shown) or the plated through holes (not shown) of the circuit board 100a. In the first embodiment, the material of the circuit layers 104 is copper, and the second conductive region 132 may be a conductive layer formed through printing, electroplating, sputtering, or dipping.

According to an important aspect of the present embodiment, the circuit board 100a has a second conductive region 132 which covers the entire third surface 130, thus, the second conductive region 132 can provide very good metal shielding function while signals are transmitted within the circuit board 100a, so that the signals transmitted within the circuit board 100a will not be interfered by electromagnetic waves coming from outside of the third surface 130 of the circuit board 100a, and the electromagnetic waves generated by the signals transmitted within the circuit board 100a will not radiate to outside of the circuit board 100a. Thus, the circuit board 100a has good EMC because of the second conductive region 132.

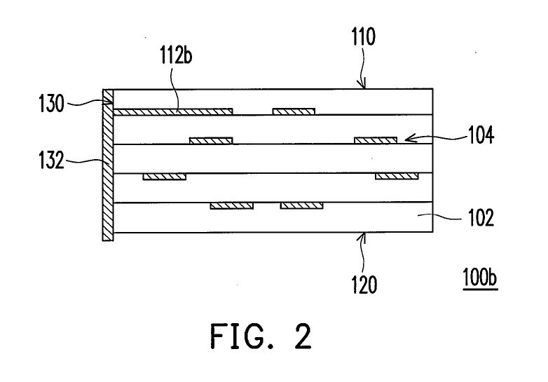

FIG. 2 is a cross-sectional view of a circuit board according to the second embodiment of the present invention. Referring to FIG. 2, compared to the first embodiment in FIG. 1B, the first conductive region 112b of the second embodiment can be a ground region in the circuit board 100b and which is formed by one of the circuit layers 104, and the edge of the first conductive region 112b can be electrically connected to the second conductive region 132 directly. In another embodiment which is not illustrated, the first conductive region 112b can be connected to the second conductive region 132 through the trace 114 in FIG. 1A.

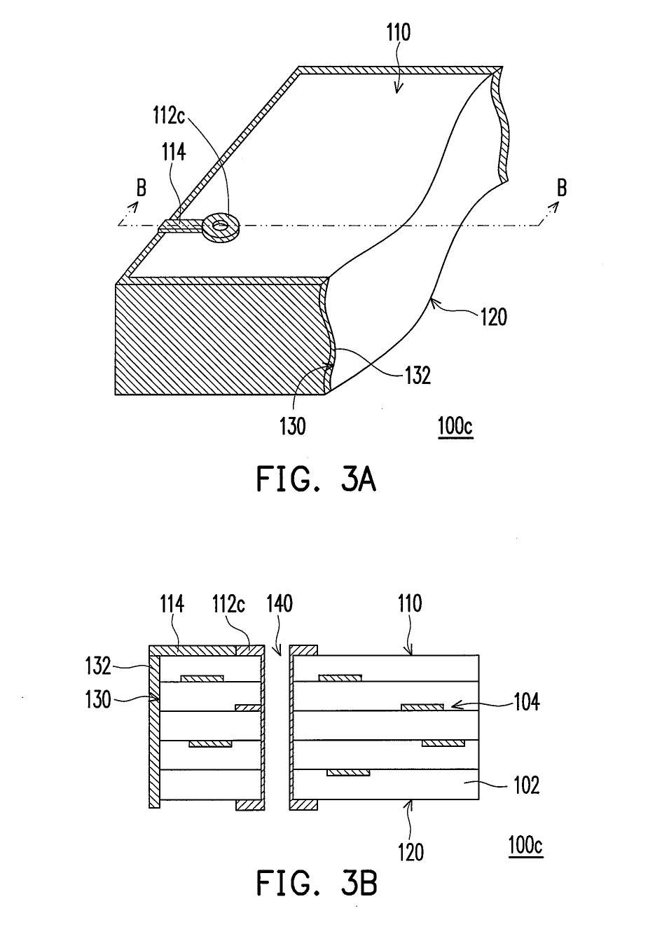

FIG. 3A is a diagram of a circuit board according to the third embodiment of the present invention, and FIG. 3B is a cross-sectional view of FIG. 3A along line B-B. In FIG. 1A and FIG. 3A, similar reference numerals refer to the similar elements throughout so they will not be described here again. Referring to FIGS. 1A, 1B, 3A, and 3B, the circuit board 100c in the third embodiment is similar to the circuit board 100a in the first embodiment except for the first conductive region 112c in the third embodiment is a via pad, and the first conductive region 112c is further electrically connected to the second conductive region 132 through the trace 114. The circuit board 100c further includes a conductive through via 140, and the first conductive region 112c is connected to one end of the conductive through via 140.

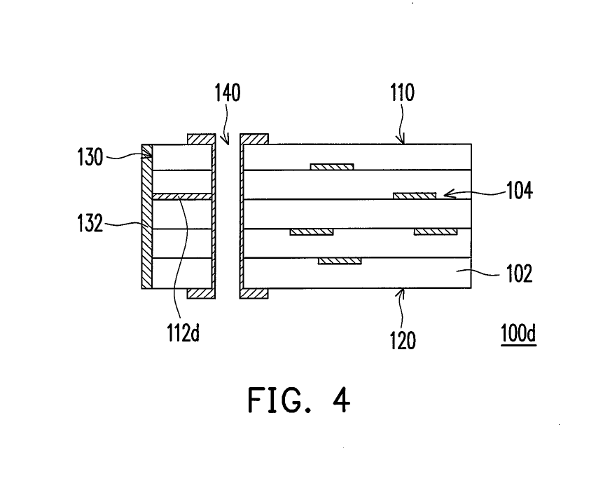

FIG. 4 is a cross-sectional view of a circuit board according to the fourth embodiment of the present invention. Referring to FIG. 4, compared to the third embodiment in FIG. 3B, the first conductive region 112d in the fourth embodiment is disposed inside the circuit board 100d, and the via pad (not shown) located on the first surface 110 may not be electrically connected to the second conductive region 132 directly, instead, it may be electrically connected to the second conductive region 132 through the conductive through via 140 and the first conductive region 112d.

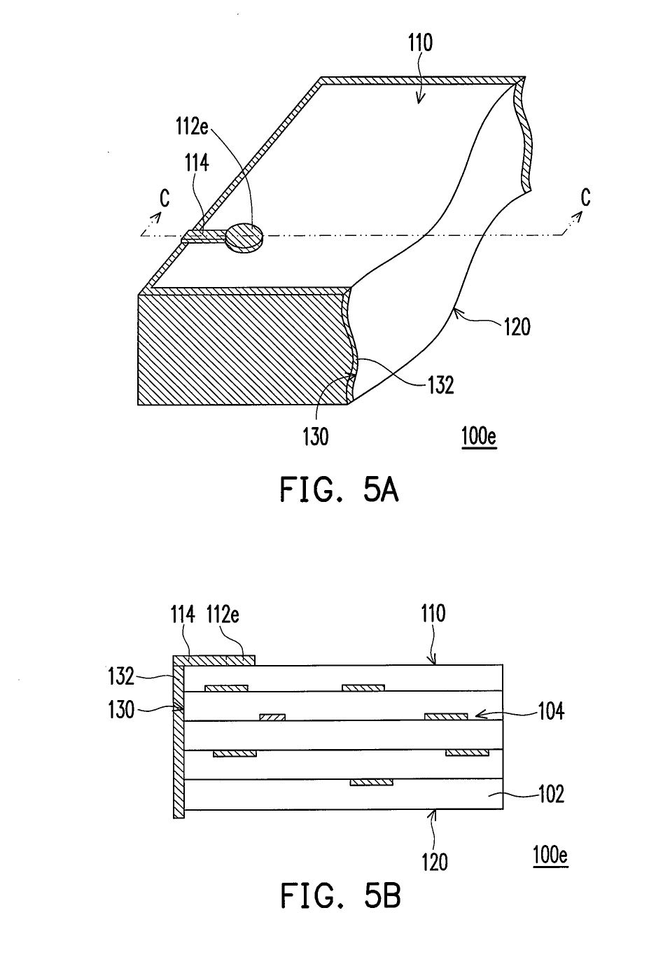

FIG. 5A is a diagram of a circuit board according to the fifth embodiment of the present invention, and FIG. 5B is a cross-sectional view of FIG. 5A along line C-C. In FIG. 3A and FIG. 5A, similar reference numerals refer to the similar elements throughout so they will not be described here again. Referring to FIGS. 3A, 5A, and 5B, the circuit board 100e in the fifth embodiment is similar to the circuit board 100c in the third embodiment except for the first conductive region 112e in the fifth embodiment is a bare copper, and the first conductive region 112e is further electrically connected to the second conductive region 132 through the trace 114.

In summary, according to the preferred embodiments of the present invention, a conductive layer is formed on the third surface of the circuit board through printing, electroplating, sputtering, or dipping, and which is used as a metal shield of the circuit board to prevent the signals transmitted within the circuit board from being interfered by electromagnetic waves coming from outside of the circuit board, or to prevent electromagnetic waves generated by the signals transmitted within the circuit board from being radiated to outside of the circuit board. Thus, the circuit board in the present invention and the electronic devices using the circuit board has good EMC.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit board, comprising:
a first surface, having at least one first conductive region formed thereon;
a second surface, being opposite to the first surface; and
a third surface, being disposed between the first surface and the second surface, the third surface being connected with the first surface and the second surface, the third surface having at least one second conductive region, the first conductive region being electrically connected to at least a part of the second conductive region.

2. The circuit board as claimed in claim 1, wherein the first conductive region is a ground region.

3. The circuit board as claimed in claim 1, wherein the first surface has a trace, the first conductive region is a bare copper, and the trace electrically connects the first conductive region and the second conductive region.

4. The circuit board as claimed in claim 1, wherein the second conductive region is a printed conductive layer, an electroplated conductive layer, a sputtered conductive layer, or a dipped conductive layer.

5. A circuit board, comprising:
a first conductive region, being disposed inside the circuit board;
a first surface;
a second surface, being opposite to the first surface; and
a third surface, being disposed between the first surface and the second surface, the third surface being connected with the first surface and the second surface, the third surface having at least one second conductive region, the first conductive region being electrically connected to at least a part of the second conductive region.

6. The circuit board as claimed in claim 5, wherein the first conductive region is a ground region.

7. The circuit board as claimed in claim 5, wherein the second conductive region is a printed conductive layer, a electroplated conductive layer, a sputtered conductive layer, or a dipped conductive layer.
